(19) United States
(12) Patent Application Publication
(10) Pub. No.: US 2009/0150112 A1
(43) Pub. Date: Jun. 11, 2009

(54) SCAN METHOD AND SYSTEM OF TESTING CHIP HAVING MULTIPLE CORES

(75) Inventor: Ishwardutt Parulkar, San Francisco, CA (US)

Correspondence Address: BROOKS KUSHMAN P.C. / SUN / STK, 1000 TOWN CENTER, TWENTY-SECOND FLOOR, SOUTHFIELD, MI, 48075-1238, US

(73) Assignee: SUN MICROSYSTEMS, INC., Santa Clara, CA (US)

(21) Appl. No.: 11/950,782

(22) Filed: Dec. 5, 2007

(51) Int. Cl. G01R 31/28

(52) U.S. Cl. 702/118

(57) ABSTRACT

A method of testing chips for manufacturing defects or operational based defects. The method may be used with any chip having logically function elements, including chips having multiple cores configured to be physically and logically identical. The method may be used to limit the total number of bits required to test the cores by demultiplexing and/or compacting the bits provided to the cores and/or outputted from the cores during a scan test.

### BACKGROUND OF THE INVENTION

1. Field of the Invention

The present invention relates to scan testing chips having multiple cores.

2. Background Art

Chip multithreading (CMT) processors and chips may include a number of cores. The cores may include flops, combination logic, and other features grouped to facilitate executing any number of operations commonly associated with integrated circuits. One or more of the cores may be the same type of core in so far as they are logically and physically the same design copied over multiple times on a die. This type of CMT can be used to integrate the power of symmetric multiprocessing (SMP) on to a single chip, allowing a single processor to execute several software threads simultaneously. Traditional single-core processors can only process one thread at a time, spending a majority of time waiting for data from memory. CMT processors can process multiple software threads using a variety of methods, such as (i) having multiple cores on a single chip (CMP), (ii) executing multiple threads on a single core (SMT), or (iii) combination of both CMP and SMT.

Scan testing may be used to test the chip for manufacturing defects. The scan testing generally corresponds with serially shifting stimulus data into scan flops in order to program the flops to executed a desired operation. The data for a particular test pattern can be arranged into a scan chain where the scan chain includes a stimulus bit for each flop required to execute the desired operation. Multiple scan chains can be used in parallel to speed testing and/or to support different test patterns. The programmed flops can then be instigated to execute the desired operation according to the stimulus data, typically according a functional clock that operations at a greater speed than a scan clock used to facilitate programming the flops. Each of the executed flops may generate a response bit to reflect its execution of the desired operation. This information can then be shifted out of the flops for analysis. A error can be determined based on whether the response bits matches with corresponding test bits.

FIG. 1 illustrates a chip 10 having a number of physically and functionally identical cores 12, 14, 16, 18 connected to a scan chain 20. This arrangement may be used to test the cores 12, 14, 16, 18 for manufacturing defects. If the chip 10 includes a C number of cores connected to the same scan chain 20, with each core having a same F number of flops, and the scan chain 20 is serially connected to each core 12, 14, 16, 18, a total of 2*C*F number of bits are required in order to scan test the cores 12, 14, 16, 18 with a single test pattern. In other words, a tester must (not shown) store C*F number of stimulus bits for scanning into the flops and another C*F number of anticipated response or test bits for comparison with the response bits scanned out each flop during a scan test (test compares each response bit as they are serially scanned out of the flops to an anticipated bit to determine errors). If the cores 12, 14, 16, 18 are to be subjected to a P number of test patterns, then a total of 2C*F*P number of bits are required in order to scan test the cores.

### BRIEF DESCRIPTION OF THE DRAWINGS

The present invention is pointed out with particularity in the appended claims. However, other features of the present invention will become more apparent and the present invention will be best understood by referring to the following detailed description in conjunction with the accompany drawings in which:

FIG. 1 illustrates a chip having a number of physically and functionally identical cores;

FIG. 2 illustrates a test configuration for testing a chip in accordance with one non-limiting aspect of the present invention;

FIG. 3 illustrates the test configuration further including a compactor in accordance with one non-limiting aspect of the present invention;

FIG. 4 illustrates the test configuration further including an additional compactor and an additional demultiplexer in accordance with one non-limiting aspect of the present invention; and

FIG. 5 illustrates the test configuration further including a scan register in accordance with one non-limiting aspect of the present invention.

### DETAILED DESCRIPTION OF THE PREFERRED EMBODIMENT(S)

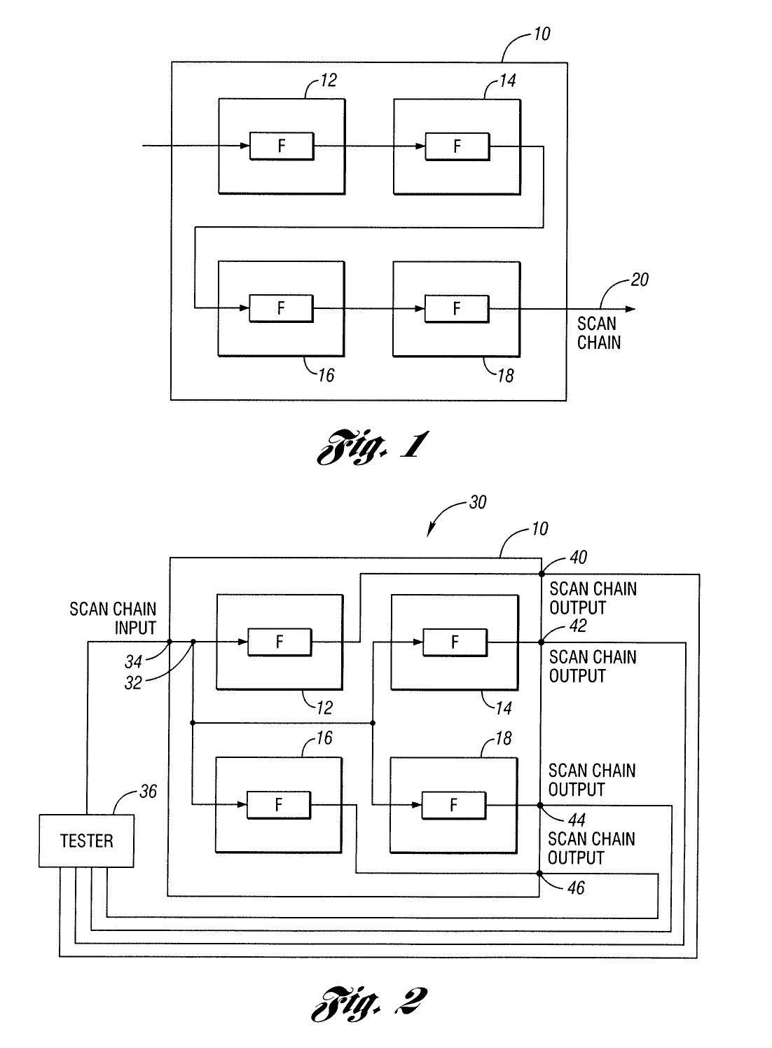

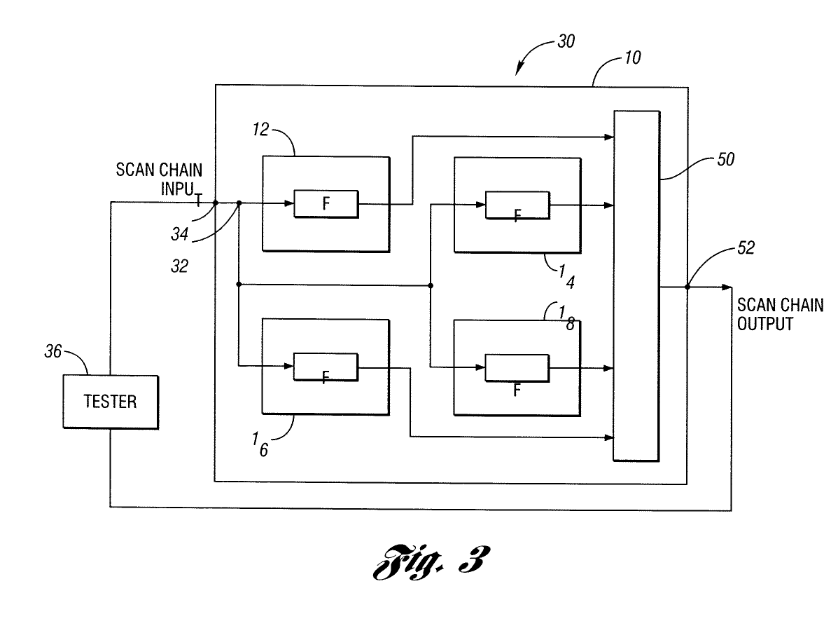

FIG. 2 illustrates a test configuration 30 for testing the chip 10 shown in FIG. 1 in accordance with one non-limiting aspect of the present invention. The test configuration 30 includes a demultiplexer 32 or fan-out device connected to a scan chain input pin 32 of the chip 10. During a scan test, the demultiplexer 30 may be configured to demultiplex stimulus bits received from a tester 36 to each of the cores 12, 14, 16, 18. The demultiplexing may correspond with the demultiplexer 32 copying/duplicating the received bits such that one bit may be inputted to the chip 10 and separately distributed or copied to each of the cores 12, 14, 16, 18. Once the bits are replicated under scan into each of the F number of flops included on each core 12, 14, 16, 18 and the flops are executed, the tester 36 compares the response bits outputted from each of the core 12, 14, 16, 18 to anticipated or test bits in order to assess errors.

With chips becoming more complex, the number of flops per chip has increased and it is not uncommon to have 1-2 million flops in a microprocessor. With geometries shrinking in advanced semiconductor process technologies, there is a need for test patterns that target complex fault models such as transition faults, path delay faults, bridging faults, multiple detect faults, etc. The number of scan test patterns required to target all these fault models in complex microprocessors has increased significantly. The increase in number of flops and in the number of test patterns has resulted in test data volumes that do not fit cost-effectively inside testers and in manufacturing test flows.

The test configuration 30 only requires the tester to output F number of bits to test C number of cores having a same F number of flops, as opposed to the C*F number of bits required to in the test arrangement described in FIG. 1. The savings becomes more dramatic if the chip 10 is to be tested according to P number of test patterns as the test is only required to output F*P number of bits, as opposed to the C*F*P number of test bits required in the test arrangement shown in FIG. 1. This allows the present invention to test any increase in the C number of cores 12, 14, 16, 18 without requiring the tester 36 to increase the number of stimulus bits C number of times. Because the outputs of each core are separately transmitted to the tester 36 from C number of output pins 40, 42, 44, 46, the tester 36 is required to compare C*F*P number response bits against the test bits in order to determine errors. The separate core outputs 40, 42, 44, 46, allow the tester 36 to identify which one of the cores 12, 14, 16, 18 has an error. The total bit processing for this arrangement is F*P(C+1).

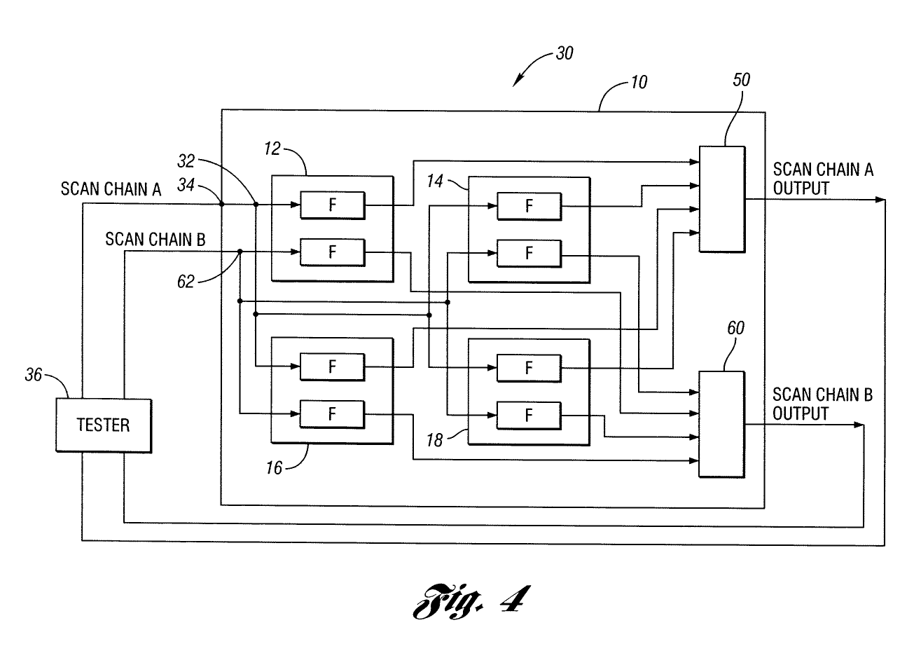

FIG. 3 illustrates the test configuration 30 further including a compactor 50 in accordance with one non-limiting aspect of the present invention. The compactor 50 can be configured to reduce the number of response bits needed for processing by the tester 36 to a single bit. This can be achieved by configuring the compactor to compare the response bit of each flop to the response bit of the corresponding flop in the other cores 12, 14, 16, 18 such that the compactor 50 outputs one value (high) if any one of the response bits fails to match with the corresponding response bit received from another one of the cores 12, 14, 16, 18 and another value (low) if all the bits match. The response bit from each flop in one core 12, 14, 16, 18 is compared to the corresponding response bit of the corresponding flop in the other cores 12, 14, 16, 18 as the bits are scanned from cores 12, 14, 16, 18 such that only a single error bit is outputted to a scan chain output pin 52.

Because the cores 12, 14, 16, 18 are logically and physically identical, the response of the cores 12, 14, 16, 18 should be the same for each test pattern. If the response of one of the cores 12, 14, 16, 18 fails to match with the other cores 12, 14, 16, 18, it can be assumed that one of the cores 12, 14, 16, 18 has an error. Optionally, the compactor 50 may be an exclusive-or gate tree configured to exclusively-or the response bit of each corresponding core 12, 14, 16, 18 as the bits are scanned out of the flops. The exclusive-or function requires the tester 36 to process a single output bit against a single test bit in order to determine whether one of the cores 12, 14, 16, 18 has an error. Once the core 12, 14, 16, 18 having the error is known, the position of the error bit with respect to the other bits shifted out of the cores 12, 14, 16, 18 can be used to identify the flop actually causing the error. Of course, the exclusive-or function is unable to detect masking errors where each of the cores 12, 14, 16, 18 have the same error at the same time, however, it is assumed that such as masking error is relatively unlikely.

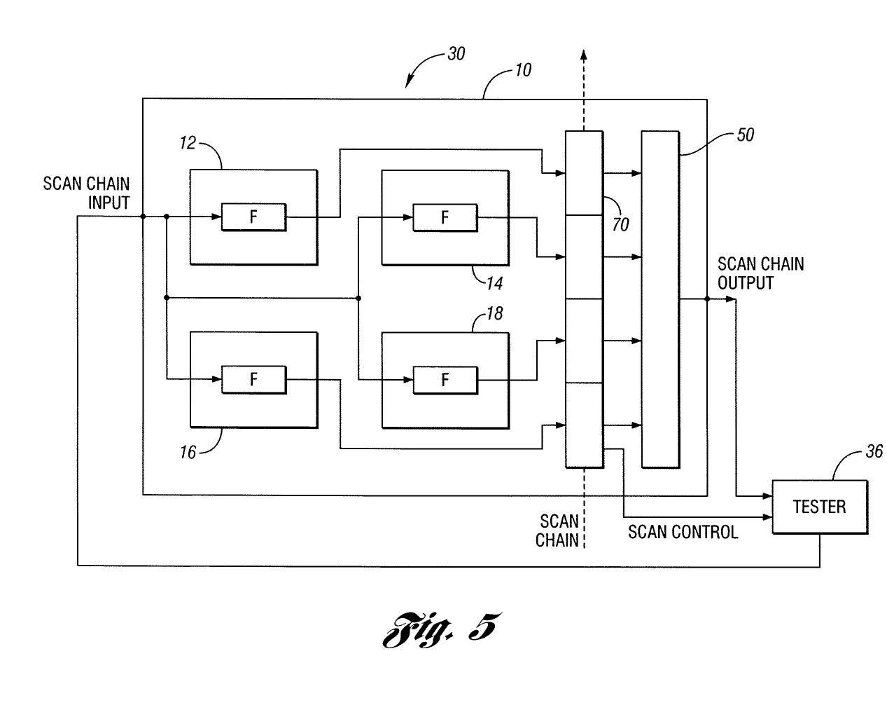

FIG. 4 illustrates the test configuration 30 further including an additional compactor 60 and an additional demultiplexer 62. These features may be included on the chip 10 to facilitate multiple chain testing. The multiple chain testing may correspond with simultaneously testing different flops on the cores 12, 14, 16, 18 with different stimulus bits, i.e., with different test patterns P. This may include a first scan chain A providing a first set of stimulus bits to a first number of flops in each core 12, 14, 16, 18 and a second scan chain B providing a second set of stimulus bits to a second number of flops in each core 12, 14, 16, 18.

The additional demultiplexer 62 and compactor 60 may operate in the same manner as the demultiplexer 32 and compactor 50 described above such that the tester need only output F*P total number of stimulus bits to program each chain of F flops for P number of patterns and the tester 36 need only process two error bits from each of the compactors 50, 60. Optionally, an additional compactor (not shown) could be included on the chip 10 to compact the outputs from the two illustrated compactors 50, 60 so as to reduce the outputted error bit to one. In this case, an error would indicate that one of the cores 12, 14, 16, 18 failed under one of the test patterns but it would be unknown whether it was in response to the first or second test pattern. Testing the chip 10 in this manner can increase the number of patterns that can be tests in the same period of time relative to the single chain testing.

In both of the above configuration shown in FIGS. 3-4, the tester 36 is only able determine the presence of an error such that it is unable to diagnosis which one or more of the cores 12, 14, 16, 18 is actually causing the error. FIG. 5 illustrates a scan register 70 being included to facilitate diagnosing which one or more of the cores 12, 14, 16, 18 is actually causing the error. The scan register 70 may include a layer of flops configured to relay the response bits from the cores 12, 14, 16, 18 as they are being scanned out to the compactor 50. The scan register 70 may be configured to store one bit at a time such that the current bit is replaced after each scan-out clock cycle with the next bit.

The ability of the scan register 70 to maintain this state information for each of cores 12, 14, 16, 18 allows the tester 36, when an error is detected, to stop scanning out the response bits and instead instigate a scan operation of the scan register 70 so that the bits in the scan register can be compared against a test bit to determine which one or more of the cores 12, 14, 16, 18 outputted a different bit relative to the other cores 12, 14, 16, 18, i.e., the core 12, 14, 16, 18 actually having the error. Once the core 12, 14, 16, 18 having the error is known, the position of the error bit with respect to the other bits shifted out of the cores 12, 14, 16, 18 can be used to identify the flop actually causing the error. Of course, the scan register 70 may be configured in any other manner and may store more than one bit. Storage of a single bit at a time for each core may be advantageous in limiting the memory demands of the chip.

A chip, for example, may include two levels of hierarchy with four identical cores at the first level and four micro-cores per core at the second level. Since all the micro-cores are identical, they need exactly the same test stimulus for a certain level of fault coverage. Also given the same test stimulus, they will generate exactly the same test response if there are no faults present. As described above, the present invention supports connecting the scan chains such that one scan-in pin of the chip fans out to each of the scan chains in the 16 micro-cores. Each bit of test stimulus data can thereby be shifted in from the pin, replicated internally into 16 bits at the fanout branches, and feeds the 16 scan chains, i.e., any test stimulus driven by the tester into the scan-in pin can be replicated to the 16 micro-cores. The ends of the 16 chains that shift out test responses can feed an exclusive-OR gate. The output of this gate can be connected to a single scan-out pin. Since the micro-cores are identical, their test responses to the replicated test stimulus is the same when there are not faults present such that as the test response is shifted out of the chains, the output of the exclusive-OR will be zero (low) in a fault-free case or one (high) if there is a fault in one or more micro-cores, the scan chains corresponding to the faulty micro-cores will have their test response different from the rest. This scheme described can be sufficient for a pass/fail test.

A diagnostic register can be used to process the test stimulus. This can be achieved by modifying the exclusive-OR into a programmable compactor, where a selected chain gets connected to the scan out pin. In a diagnosis mode, each chain can be connected directly to the scan-out pin and multiple test runs with different scan chains connected to the scan-out pin can be performed to identify the faulty core. Another way to do this is to connect all 16 chains to 16 different scan-out pins which will be used only when diagnosing and not during manufacturing test. If the multiple runs need to be reduced further an on-chip signature compressor can be added at the ends of each of the chains and an exclusive-OR of the signatures can be performed. In test mode, the exclusive-OR is visible to the tester and in diagnosis mode, each of the signatures can be looked at via a scan or any other slow test port. attachments: A.

One non-limiting aspect of the present invention relates to reducing test data volume of scan patterns for CMT processors. Reducing the scan data volume allows for better utilization of tester memory. The savings in tester memory can be used towards fitting in other test patterns, thus increasing the overall test coverage and improving the outgoing quality and reducing test escapes in manufacturing. Test patterns targeting a wide range of fault models and a larger number of patterns can be fit in the available tester memory. The present invention, for a fixed level of test coverage or quality, can reduced the test time and tester memory. The invention is not restricted to CMT processors and be applied to any chip design that has multiple instances of design blocks that are logically and physically identical.

As required, detailed embodiments of the present invention are disclosed herein; however, it is to be understood that the disclosed embodiments are merely exemplary of the invention that may be embodied in various and alternative forms. The figures are not necessarily to scale, some features may be exaggerated or minimized to show details of particular components. Therefore, specific structural and functional details disclosed herein are not to be interpreted as limiting, but merely as a representative basis for the claims and/or as a representative basis for teaching one skilled in the art to variously employ the present invention.

While embodiments of the invention have been illustrated and described, it is not intended that these embodiments illustrate and describe all possible forms of the invention. Rather, the words used in the specification are words of description rather than limitation, and it is understood that various changes may be made without departing from the spirit and scope of the invention.

What is claimed is:

1. A method of testing a chip having a number of cores, the method comprising:
determining a test pattern for testing a desired operation of at least C number of cores, each of the C number of cores being logically identical such that each core includes a same F number of flops to execute the desired operation, the test pattern specifying stimulus bits for use by the flops to execute the desired operation;
presenting no more than F number of stimulus bits to the chip for programming the C*F number of flops to execute the desired operation;
instigating the flops to execute the desired operation according to the programmed stimulus bits, the flops generating a response bit upon execution of the desired operation; and
determining an error in the chip based on whether the response bits match with corresponding test bits.

2. The method of claim 1 further comprising outputting the stimulus bits from a tester connected to a test pin included on the chip.

3. The method of claim 2 further comprising connecting a demultiplexer included on the chip to one of the test pin receiving the stimulus bits, the demultiplexer configured to demultiplex the F number of stimulus bits to the C number of cores such that at total C*F number of stimulus bits are demultiplexed to the cores.

4. The method of claim 1 further comprising outputting a single error bit to represent the error in the chip.

5. The method of claim 4 further comprising outputting the single error bit by exclusive-oring the stimulus bits from each core with the other cores.

6. The method of claim 5 further comprising relaying the response bits outputted from each core to a compactor for exclusive-oring with the other cores with a scan register configured to maintain state information for the relayed stimulus bits.

7. The method of claim 6 further comprising analyzing the state information to diagnose which one of the cores has the error.

8. The method of claim 7 further comprising:
determining another test pattern for testing a another desired operation of at least C number of cores, each of the C number of cores being logically identical such that each core includes a same F number of flops to execute the another desired operation, the test pattern specifying stimulus bits for use by the flops to execute the another desired operation;
presenting no more than F number of stimulus bits to the chip for programming the C*F number of flops to execute the another desired operation;
instigating the flops to execute the another desired operation according to the programmed stimulus bits, the flops generating a response bit upon execution of the another desired operation;
determining another error in the chip based on whether the response bits from the another desired operation match with corresponding test bits; and
outputting another single error bit to represent the another error in the chip.

9. The method of claim 8 further comprising simultaneously presenting the stimulus bits for the desired operation and the another desired operation and simultaneously instigating the flops to execute the desired operation and the another desired operation in order to simultaneously determine errors in the chips associated with the desired operation and the another desired operation.

10. A method of testing a chip having a number of cores, the method comprising:
determining a test pattern for testing a desired operation of at least C number of cores, each of the C number of cores being logically identical such that each core includes a same F number of flops to execute the desired operation, the test pattern specifying stimulus bits for use by the flops to execute the desired operation;
programming the C*F number of flops to execute the desired operation;
instigating the flops to execute the desired operation, the flops generating a response bit upon execution of the desired operation;
compacting the C*F number of response bits to a single response bit and
determining an error based on whether the single response bit matches with a single test bit.

11. The method of claim 10 further comprising configuring the test pattern to include at least two different test patterns for testing at least two different operations such that C*F number of flops are programmed for each operation and the error for each operation is determined based on whether the single response bit for each operation matches with the test bit.

12. The method of claim 11 further comprising sequencing the at least two test patterns such that only one operation is tested at a time.

13. The method of claim 11 further comprising simultaneously executing the at least two test patterns such that the at least two operations are tested at the same time.

14. The method of claim 10 further comprising demultiplexing F number bits to program the C*F number of flops such that a total of C*F number of bits are demultiplexed to the cores.

15. The method of claim 14 further comprising compacting the response bits to determine the error such that a total of P(F+1) number of bits are used to test the chip according to the P number of test patterns.

16. A method of testing a chip having a number of cores, the method comprising:
determining a test pattern for testing a desired operation of at least C number of cores, each of the C number of cores being logically identical such that each core includes a same F number of flops to execute the desired operation, the test pattern specifying stimulus bits for use by the flops to execute the desired operation;
shifting F number of stimulus bits to the chip as part of a scan test demultiplexing the F number of stimulus bits to the C*F number of flops to execute the desired operation;
instigating the flops to execute the desired operation according to the programmed stimulus bits as part of the scan test, the flops generating a response bit upon execution of the desired operation;
shifting the C*F number response bits out of the C*F number of flops; and
determining an error in the chip based on whether the response bits match with corresponding test bits.

17. The method of claim 16 further comprising compacting the C*F number of response bits to a single response bit and determining the error based on whether the single response bit matches with a single test bit.

18. The method of claim 17 further comprising performing the compacting by exclusive-oring the C*F number of response bits with each other.

19. The method of claim 17 further comprising temporarily storing each response bit in a scan register such that the stored test bits are retrievable if the error is determined.

20. The method of claim 16 further comprising separately shifting the response bits from the chip to determine the error such that a total of 2*F number of bits are used to test the chip.
